(19) United States
(12) Patent Application Publication
(10) Pub. No.: US 2025/0287528 A1
(43) Pub. Date: Sep. 11, 2025

(54) LIQUID COOLING SYSTEM

(71) Applicant: COOLER MASTER CO., LTD., Taipei City (TW)

(72) Inventors: Tung-Yang SHIEH, Taipei City (TW); Chien-Liang LIN, Taipei City (TW)

(73) Assignee: COOLER MASTER CO., LTD., Taipei City (TW)

(21) Appl. No.: 19/073,939

(22) Filed: Mar. 7, 2025

(30) Foreign Application Priority Data
Mar. 8, 2024 (TW) 113202380

(51) Int. Cl. H05K 7/20

(52) U.S. Cl. CPC H05K 7/20254; H05K 7/20263; H05K 7/20272

(57) ABSTRACT

A liquid cooling system includes a cold plate, a first water block and a second water block, a first radiator and a second radiator, a plurality of first fans and at least one second fan, a plurality of first pipes connecting the first water block and the second water block to the first radiator, and a plurality of second pipes connecting the cold plate to the second radiator, respectively configured to circulate a first working fluid and a second working fluid within the liquid cooling system to dissipate heat from connected components, and a thermoelectric cooler module having a hot side and a cold side that are opposite each other. The cold side is thermally coupled to the first water block, and the hot side is thermally coupled to the cold plate.

### CROSS-REFERENCE TO RELATED APPLICATIONS

This U.S. application claims the benefits of priority to Taiwan application No. 113202380, filed on Mar. 8, 2024, titled “Water Cooling Heat Dissipation Module” of which is incorporated herein by reference in its entirety.

### BACKGROUND

The present disclosure relates to a liquid cooling system, particularly to a liquid cooling system that includes a thermoelectric cooler module.

With significant technological breakthroughs, computers have become indispensable instruments in our daily life. As electronic components like graphics cards, processors, or other similar electronic devices continue enhancing processing speed and performance, they also generate substantial heat during operation. The heat generation can result in overheating, diminished performance, and potentially irreversible damage if temperatures rise excessively.

To resolve the problems mentioned above, water cooling systems are commonly used to enhance heat dissipation for electronic devices. Conventional water cooling systems include a water cooling block, a water cooling radiator, and a pump. However, the cooling efficiency of water cooling systems is currently constrained by the limited space in electronic devices. Therefore, enhancing the cooling efficiency of water cooling systems within confined spaces is a challenge that R&D in this field strives to address.

### SUMMARY

In general terms, this disclosure is directed to a liquid cooling system. In some embodiments, and by non-limiting example, the present disclosure provides a liquid cooling system that enhances cooling efficiency within limited spaces of electronic devices.

Aspects of the present disclosure provide a liquid cooling system. The liquid cooling system includes a cold plate, a first water block and a second water block, a first radiator and a second radiator, a plurality of first fans and at least one second fan, a plurality of first pipes connecting the first water block and the second water block to the first radiator, and a plurality of second pipes connecting the cold plate to the second radiator, configured to circulate a first working fluid and a second working fluid within the liquid cooling system to dissipate heat from connected components, and a thermoelectric cooler module having a hot side and a cold side that are opposite each other, wherein the cold side is thermally coupled to the first water block, and the hot side is thermally coupled to the cold plate.

In one embodiment, the second water block is thermally coupled to a heat source.

In one embodiment, the first fans are disposed on the first radiator and the second fan is disposed on the second radiator, the first fans and the second fan being configured to dissipate heat from the first radiator and the second radiator, respectively.

In one embodiment, the first water block, the second water block, and the first radiator are fluidly connected via the first pipes to form a first circulation loop.

In one embodiment, the cold plate and the second radiator are fluidly connected via the second pipes to form a second circulation loop.

In one embodiment, the first circulation loop and the second circulation loop are independent of each other.

In one embodiment, the first circulation loop contains a first working fluid and the second circulation loop contains a second working fluid, each working fluid circulating independently within the respective loop.

In one embodiment, the liquid cooling system further comprises a micro pump that is disposed within the cold plate and configured to pump the second working fluid into the second radiator to circulate the second working fluid within the second circulation loop.

In one embodiment, the first working fluid and the second fluid include water or acetone, or other heat dissipating fluids.

Another aspect of the present disclosure provides a liquid cooling assembly. The liquid cooling assembly includes a first water block and a second water block, a first radiator and a second radiator, a plurality of first fans and at least one second fan, and a plurality of first pipes connecting the first water block and the second water block to the first radiator, and a plurality of second pipes connecting a cold plate to the second radiator, respectively configured to circulate a first working fluid and a second working fluid within a liquid cooling system to dissipate heat from connected components.

In one embodiment, the second water block is thermally coupled to a heat source.

In one embodiment, the first fans are disposed on the first radiator and the second fan is disposed on the second radiator, the first fans and the second fan being configured to dissipate heat from the first radiator and the second radiator, respectively.

In one embodiment, the first water block, the second water block, and the first radiator are fluidly connected via the first pipes to form a first circulation loop.

In one embodiment, the first circulation loop contains and circulates the first working fluid.

In one embodiment, the first working fluid and the second fluid include water or acetone, or other heat dissipating fluids.

Still another aspect provides a cold plate module. The cold plate module includes a cold plate, and a thermoelectric cooler module having a hot side and a cold side that are opposite each other, wherein the cold side is thermally coupled to a first water block, and the hot side is thermally coupled to the cold plate.

In one embodiment, the cold plate module further comprises a second radiator and a plurality of second pipes, wherein the cold plate and the second radiator are fluidly connected via the second pipes to form a second circulation loop, and a second working fluid is contained within the second circulation loop.

In one embodiment, the cold plate module further comprises a micro pump that is disposed within the cold plate and configured to pump the second working fluid into the second radiator to circulate the second working fluid within the second circulation loop.

In one embodiment, the cold plate module further comprises at least one second fan disposed on the second radiator and configured to dissipate heat from the second radiator.

In one embodiment, the second fluid includes water or acetone, or other heat dissipating fluids.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

FIG. 1 is a perspective schematic view of a liquid cooling system according to one embodiment of the present disclosure.

FIG. 2 is an enlarged schematic view of a cold plate region of the liquid cooling system in FIG. 1.

FIG. 3 is an exploded schematic view of the cold plate region of the liquid cooling system in FIG. 1.

FIG. 4 is a perspective schematic view of a liquid cooling system of FIG. 1 with additional flow diagrams.

### DETAILED DESCRIPTION

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

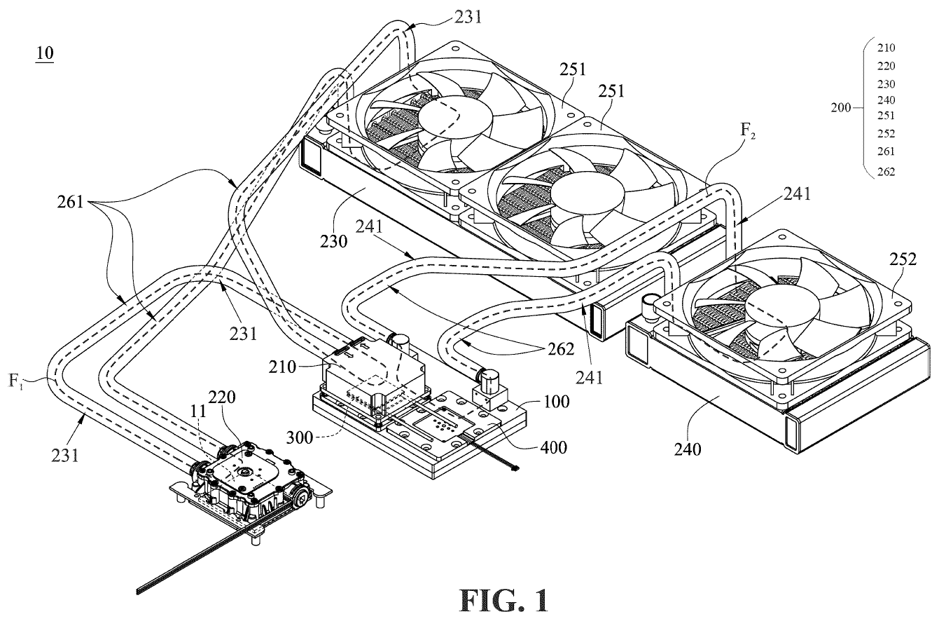

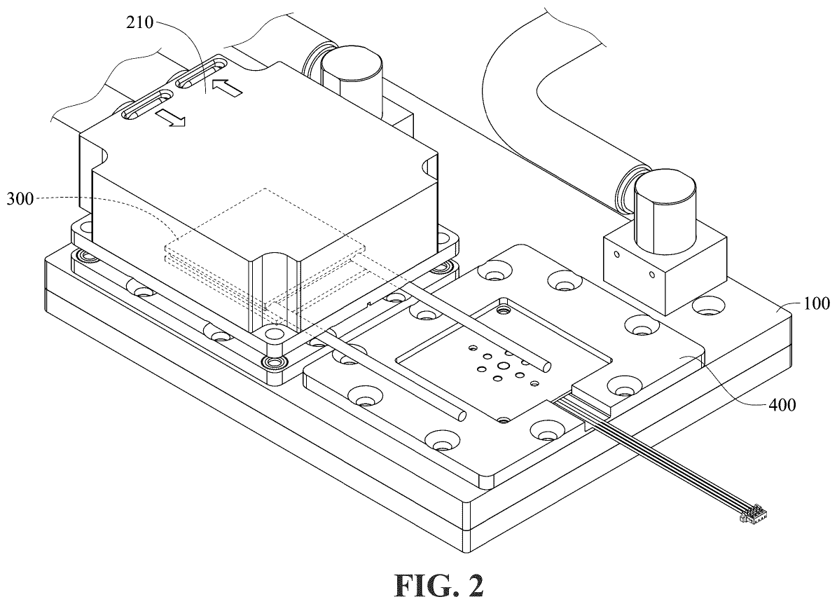

Referring to FIGS. 1 and 2. FIG. 1 is a perspective schematic view of an example liquid cooling system 10 according to one embodiment of the present disclosure. FIG. 2 is an enlarged schematic view of a cold plate 100 region of the example liquid cooling system 10 in FIG. 1. As shown in FIG. 1, the example liquid cooling system 10 includes a cold plate 100, a liquid cooling assembly 200, a thermoelectric cooler module 300, and a micro pump 400.

In one embodiment, the cold plate 100, also known as a liquid cooling plate, is a component in liquid cooling systems designed to manage and dissipate heat generated by electronic devices, such as central processing units (CPUs), graphic processing units (GPUs), and other similar power electronics. The cold plate 100 is typically constructed from thermally conductive materials such as copper or aluminum to transfer heat from the device. As an example shown in FIG. 1, the cold plate 100 is designed to transfer heat away from the thermoelectric cooler module 300.

In one embodiment, the liquid cooling assembly 200 includes a first liquid block 210, a second liquid block 220, a first radiator 230, a second radiator 240, a plurality of first fans 251, a second fan 252, a plurality of first pipes 261, and a plurality of second pipes 262. The first liquid block 210, second liquid block 220, and the first radiator 230 are connected via the first pipes 261 to form a first circulation loop 231, as shown in the dot lines. The second liquid block 220 is thermally coupled to a heat source 11. The first circulation loop 231 is filled with a first working fluid F1, which circulates through the loop and dissipates heat from the heat source 11 via the second liquid block 220.

For example, the liquid cooling assembly 200 serves as the primary cooling system, ensuring that heat generated by the heat source 11 is efficiently absorbed and dissipated through the first radiator 230 and the second radiator 240, with the assistance of the first fans 251 and the second fan 252. This structured design enables the liquid cooling assembly 200 to operate effectively within limited spaces while maintaining high heat dissipation efficiency.

In one embodiment, the cold plate 100 and the second radiator 240 are connected via the second pipes 262 to form a second circulation loop 241, as shown in the dot lines. The second circulation loop 241 is filled with a second working fluid F2, which flows through the loop to dissipate heat from the thermoelectric cooler module 300 via the cold plate 100. In the embodiment, the first circulation loop 231 and the second circulation loop 241 are independent and not interconnected. However, the embodiment is not limited thereto. In other embodiments, the first circulation loop and the second circulation loop can be interconnected via a thermal exchange interface, such as a shared heat exchanger or a controlled valve system, allowing an option for heat transfer between the loops to optimize cooling performance under different operating conditions.

In one embodiment, the first working fluid F1 and the second working fluid F2 can be cooling liquids such as water or acetone, but the embodiment is not limited thereto. In other embodiments, other suitable heat dissipating cooling liquids can also be used as the working fluid. The selection of an appropriate working fluid is contingent upon considerations like thermal efficiency, environmental ramification, compatibility with system materials and operational safety.

In one embodiment, the first fans 251 are positioned on the first radiator 230 to direct airflow across its surface, enhancing the heat dissipation capabilities. Similarly, the second fan 252 is mounted on the second radiator 240, facilitating airflow and enhancing the heat dissipation efficiency.

In one embodiment, the number of the first fans 251 can be, for example, two, but the embodiment is not limited thereto. In other embodiments, the number of first fans can be zero, one, three or more.

In one embodiment, the number of the second fan 252 can be, for example, one, but the embodiment is not limited thereto. In other embodiments, the number of second fans can be zero, two or more.

In one embodiment, the heat source 11 can be, for example, a central processing unit (CPU) or a graphics processing unit (GPU), but the embodiment is not limited thereto. In other embodiments, the heat source can also be an expansion card, a resistor, a capacitor, or other electronic components.

In one embodiment, the second liquid block 220 may include, for example, a pump (not shown) for driving the first working fluid F1 into the first radiator 230 and circulating the first working fluid F1 within the first circulation loop 231, thereby enhancing the heat dissipation effect of the liquid cooling assembly 200.

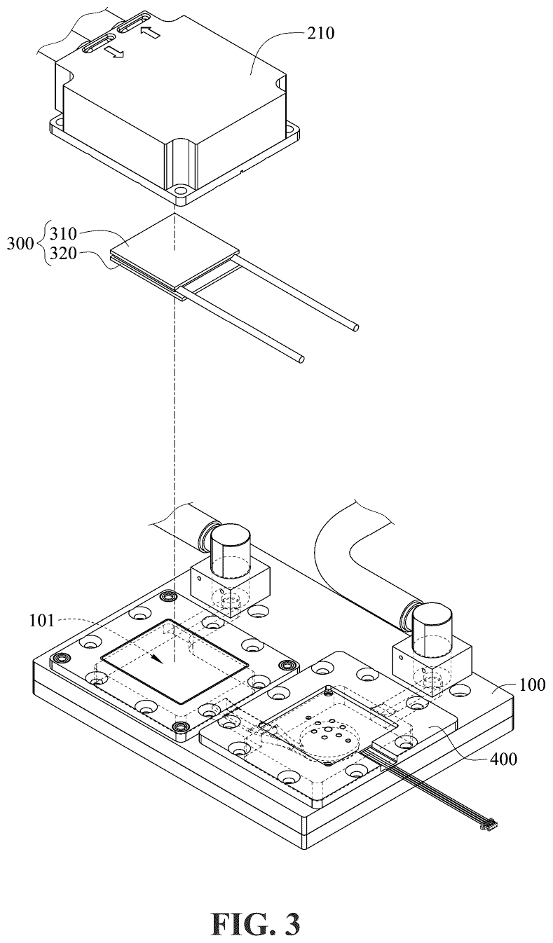

Referring to FIG. 3. FIG. 3 is an exploded schematic view of the cold plate 100 region of the example liquid cooling system in FIG. 1. As an example shown in FIG. 3, the cold plate 100 includes an accommodation space 101 for the second working fluid F2 to flow. The thermoelectric cooler module 300 includes a cold side 310 and a hot side 320. The cold side 310 is thermally coupled to the first liquid block 210, while the hot side 320 is thermally coupled to the cold plate 100.

In one embodiment, the cold side 310 of the thermoelectric cooler module 300 is thermally coupled to the first liquid block 210 to cool the first working fluid F1 (as shown in FIG. 1), while the second working fluid F2 (as shown in FIG. 1) cools the hot side 320 of the thermoelectric cooler module 300.

In one embodiment, the thermoelectric cooler module 300 is a temperature control component. When powered with direct current, it utilizes the Peltier effect of the thermoelectric cooler module 300 to absorb heat through its cold side 310 and release heat through its hot side 320. In other words, the thermoelectric cooler module 300 can be selectively powered on or off to adjust the cooling efficiency of the first working fluid F1 in the first circulation loop 231 (as shown in FIG. 1).

The Peltier effect is a thermoelectric phenomenon in which heating or cooling occurs at an electrified junction of two different conductors. When a direct current (DC) flows through the circuit of two dissimilar conductors, heat is absorbed at one junction (the cold side) and released at the other junction (the hot side), creating a temperature difference.

The Peltier effect is the basis for Peltier devices, also known as thermoelectric coolers (TECs) or Peltier elements. These devices are used in applications where heat needs to be transferred from one place to another, such as in small cooling systems, electronic component cooling, and portable refrigerators. The ability to control the direction and magnitude of heat transfer by adjusting the polarity and magnitude of the electrical current makes Peltier devices versatile for precise temperature control applications. Unlike traditional cooling methods, Peltier coolers do not have moving parts or require refrigerants, which makes them environmentally friendly and maintenance-free.

In one embodiment, the micro pump 400 is disposed on the cold plate 100. The installation of the micro pump 400 facilitates the propulsion of the second working fluid F2 into the second radiator 240 (as shown in FIG. 1), thereby maintaining continuous circulation within the second circulation loop 241 (as shown in FIG. 1). Further, the configuration enhances the cooling efficiency of the cold plate 100. Additionally, the internal flow architecture of the cold plate 100 may incorporate microchannels or fin arrays designed to expand the contact surface area and augment thermal conductivity for optimizing heat dissipation.

In one embodiment, a micro pump 400 is installed to enable active circulation within the second circulation loop 241, thereby enhancing the cooling efficiency of the cold plate 100. However, the embodiment is not limited thereto. In other embodiments, the micro pump may be omitted, allowing the second circulation loop to operate as a passive circulation system. For example, when power consumption is taken into account, removing the micro pump eliminates its energy consumption, making the system more power-efficient.

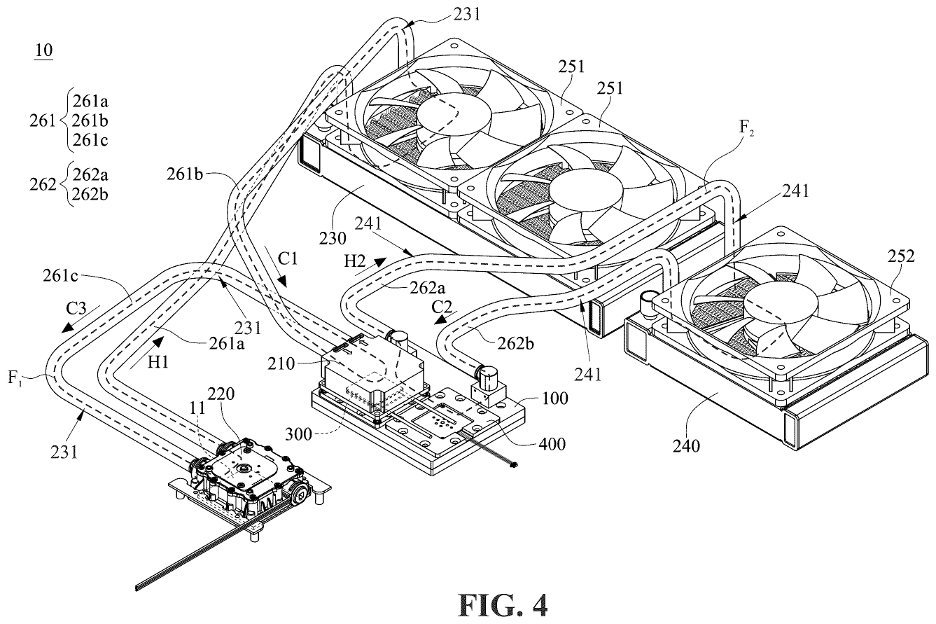

Referring to FIG. 4. FIG. 4 is a perspective schematic view of the example liquid cooling system 10 of FIG. 1 with additional flow diagrams illustrating the flow of the first working fluid F1 and the second working fluid F2.

As an example shown in FIG. 4, in the first circulation loop 231, the first working fluid F1 dissipates heat from the heat source 11 through the second liquid block 220, absorbing the heat energy generated by the heat source. Subsequently, the first working fluid F1 flows into the first radiator 230 through a first segment of the first pipes 261a in the H1 direction and dissipates heat via one of the first fans 251. After cooling, the first working fluid F1 flows through a second segment of first pipes 261b in the C1 direction to the first liquid block 210, where it undergoes further cooling by the thermoelectric cooler module 300. Finally, the first working fluid F1 flows through a third segment of the first pipes 261c in the C3 direction to the second liquid block, where it again dissipates heat from the heat source 11.

In the second circulation loop 241 of the embodiment, the second working fluid F2 flows within the accommodating space 101 of the cold plate 100 to dissipate heat from the hot side 320 of the thermoelectric cooler module 300, absorbing the heat energy generated by the hot side 320. Subsequently, the second working fluid F2 flows into the second radiator 240 through a first segment the second pipe 262a in the H2 direction and dissipates heat via the second fan 252. After cooling, the second working fluid F2 flows through a second segment the second flow pipe 262b in the C2 direction back into the accommodating space 101, where it again dissipates heat from the hot side 320 of the thermoelectric cooler module 300.

In the liquid cooling system described in the aforementioned embodiments, the integration of a thermoelectric cooler module with the liquid cooling components introduces a synergistic cooling effect that significantly enhances the performance of the existing liquid cooling system. The thermoelectric cooler module, which operates based on the Peltier effect, is thermally coupled to key components of the liquid cooling setup. This strategic coupling allows the thermoelectric cooler to directly influence the temperature of the working fluid circulating within the system.

By leveraging the capability of the thermoelectric cooler to actively cool below ambient temperature, the temperature of the working fluid is further reduced as it passes through the module. This reduction in fluid temperature means that the liquid is able to absorb more heat from the components, such as processors or graphics cards, before it returns to the radiator. As a result, the overall cooling efficiency of the system is significantly enhanced.

Further, this integration of the thermoelectric cooler not only enhances the thermal management but does so without requiring additional space. This is particularly advantageous in applications where space is at a premium, such as in compact electronic devices or densely packed server environments. The combined configuration provides greater heat dissipation capability, allowing crucial components to operate at ideal temperature while potentially extending their lifespan due to reduced thermal stress. Thus, the addition of a thermoelectric cooler module to a liquid cooling system provides a powerful and space-saving solution to the management of heat in high-performance computing and electronic systems.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. Of course, the disclosed embodiments are merely exemplary embodiments and that various modifications can be made without departing from the spirit and scope of the disclosure. Further, it should be understood that various aspects of the embodiment are not mutually exclusive of each other and can be combined as desired by a person of ordinary skill in the art as a matter of design choices.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A liquid cooling system comprising:
a cold plate;
a first water block and a second water block;
a first radiator and a second radiator;
a plurality of first fans and at least one second fan;
a plurality of first pipes connecting the first water block and the second water block to the first radiator, configured to circulate a first working fluid within the liquid cooling system;
a plurality of second pipes connecting the cold plate to the second radiator, configured to circulate a second working fluid within the liquid cooling system; and
a thermoelectric cooler module having a hot side and a cold side that are opposite each other, wherein the cold side is thermally coupled to the first water block, and the hot side is thermally coupled to the cold plate.

2. The liquid cooling system of claim 1, wherein the second water block is thermally coupled to a heat source.

3. The liquid cooling system of claim 1, wherein the first fans are disposed on the first radiator and the second fan is disposed on the second radiator, the first fans and the second fan being configured to dissipate heat from the first radiator and the second radiator, respectively.

4. The liquid cooling system of claim 1, wherein the first water block, the second water block, and the first radiator are fluidly connected via the first pipes to form a first circulation loop.

5. The liquid cooling system of claim 4, wherein the cold plate and the second radiator are fluidly connected via the second pipes to form a second circulation loop.

6. The liquid cooling system of claim 5, wherein the first circulation loop and the second circulation loop are independent of each other.

7. The liquid cooling system of claim 5, wherein the first circulation loop contains a first working fluid and the second circulation loop contains a second working fluid, each working fluid circulating independently within the respective loop.

8. The liquid cooling system of claim 7, further comprises a micro pump that is disposed within the cold plate and configured to pump the second working fluid into the second radiator to circulate the second working fluid within the second circulation loop.

9. The liquid cooling system of claim 1, wherein the first working fluid and the second fluid include water or acetone, or other heat dissipating fluids.

10. A liquid cooling assembly, comprising:
a first water block and a second water block;
a first radiator and a second radiator;
a plurality of first fans and at least one second fan; and
a plurality of first pipes connecting the first water block and the second water block to the first radiator, configured to circulate a first working fluid within the liquid cooling system; and
a plurality of second pipes connecting the cold plate to the second radiator, configured to circulate a second working fluid within the liquid cooling system.

11. The liquid cooling assembly of claim 10, wherein the second water block is thermally coupled to a heat source.

12. The liquid cooling assembly of claim 10, wherein the first fans are disposed on the first radiator and the second fan is disposed on the second radiator, the first fans and the second fan being configured to dissipate heat from the first radiator and the second radiator, respectively.

13. The liquid cooling assembly of claim 10, wherein the first water block, the second water block, and the first radiator are fluidly connected via the first pipes to form a first circulation loop.

14. The liquid cooling assembly of claim 13, wherein the first circulation loop contains and circulates the first working fluid.

15. The liquid cooling assembly of claim 10, wherein the first working fluid and the second fluid include water or acetone, or other heat dissipating fluids.

16. A cold plate module, comprising:
a cold plate; and
a thermoelectric cooler module having a hot side and a cold side that are opposite each other, wherein the cold side is thermally coupled to a first water block, and the hot side is thermally coupled to the cold plate.

17. The cold plate module of claim 16, further comprising a second radiator and a plurality of second pipes, wherein the cold plate and the second radiator are fluidly connected via the second pipes to form a second circulation loop, and a second working fluid is contained within the second circulation loop.

18. The cold plate module of claim 17, further comprising a micro pump that is disposed within the cold plate and configured to pump the second working fluid into the second radiator to circulate the second working fluid within the second circulation loop.

19. The cold plate module of claim 17, further comprising at least one second fan disposed on the second radiator and configured to dissipate heat from the second radiator.

20. The cold plate module of claim 17, wherein the second fluid includes water or acetone, or other heat dissipating fluids.
